(19) United States
(12) Patent Application Publication
(10) Pub. No.: US 2015/0122465 A1
(43) Pub. Date: May 7, 2015

(54) HEAT SINK DEVICE

(71) Applicant: KABUSHIKI KAISHA TOYOTA JIDOSHOKKI, Kariya-shi (JP)

(72) Inventors: Shogo MORI, Aichi-ken (JP); Yuri OTOBE, Aichi-ken (JP); Shinsuke NISHI, Aichi-ken (JP)

(73) Assignee: KABUSHIKI KAISHA TOYOTA JIDOSHOKKI, Kariya-shi (JP)

(21) Appl. No.: 14/524,478

(22) Filed: Oct. 27, 2014

(30) Foreign Application Priority Data
Nov. 5, 2013 (JP) 2013-229723

(51) Int. Cl. H05K 7/20; F28D 15/00

(52) U.S. Cl. CPC H05K 7/20218; F28D 15/00
USPC 165/104.33

(57) ABSTRACT

A refrigerant inlet header 30 is in communication with a cooling unit 20 in a longitudinal lateral surface 20C of the refrigerant inlet header 30. Cooling fluid is flowed into the cooling unit 20 through the part where the refrigerant inlet header 30 is in communication with the cooling unit 20. A refrigerant outlet header 40 is in communication with the cooling unit 20 in a longitudinal lateral surface 20D of the refrigerant outlet header 40. Cooling fluid is flowed out through the part where the refrigerant outlet header 40 is in communication with the cooling unit 20. In a passage of the cooling unit 20 for cooling fluid, a plurality of pin fins 25 is disposed in a stagger arrangement along the longitudinal direction of the refrigerant inlet and outlet headers 30 and 40.

### BACKGROUND OF THE INVENTION

The present invention relates to a heat sink device.

Japanese Patent Application Publication No. 2008-294128 discloses a cooling device having two spaced headers in which cooling fluid flows and a cooling unit disposed between the two headers and having therein a fluid passage in which the cooling fluid flows. Objects which need to be cooled are mounted on one surface of the cooling unit.

Semiconductor elements are mounted on the cooling unit disposed between the two headers. One end of the header serves as an inlet or an outlet for cooling fluid and the other end of the header is closed and the flow speed of the cooling fluid adjacent to the inlet of the header is different from that adjacent to the closed end of the header. Therefore, the flow speed of the cooling fluid flowing in the cooling unit varies with different positions in the extending direction of the header, so that the performance of the cooling unit to cool the semiconductor elements varies with different positions of the semiconductor elements. Specifically, the cooling performance is decreased toward the closed end of the header.

The present invention is directed to providing a heat sink device that prevents variation in the cooling performance of a cooling unit.

### SUMMARY OF THE INVENTION

In accordance with an aspect of the present invention, there is provided a heat sink device including a cooling unit having a refrigerant passage through which refrigerant is flowed and mounting a semiconductor element, a refrigerant inlet header having a tubular shape, a refrigerant outlet header having a tubular shape and extending in parallel with the refrigerant inlet header, and a plurality of pin fins placed side by side in the refrigerant passage of the cooling unit along the longitudinal direction of the refrigerant inlet header and the refrigerant outlet header. One end of the refrigerant inlet header is closed and the other end of the refrigerant inlet header has an opening which allows the refrigerant to flow into the refrigerant inlet header. The refrigerant inlet header has a lateral surface in a longitudinal direction thereof and is in communication with the cooling unit through the lateral surface thereof so as to allow the refrigerant in the refrigerant inlet header to flow into the cooling unit. One end of the refrigerant outlet header is closed and the other end of the refrigerant outlet header has an opening which allows the refrigerant to flow out from the refrigerant outlet header. The refrigerant outlet header has a lateral surface in a longitudinal direction thereof and is in communication with the cooling unit through the lateral surface thereof so as to allow the refrigerant to flow out from the cooling unit.

Other aspects and advantages of the invention will become apparent from the following description, taken in conjunction with the accompanying drawings, illustrating by way of example the principles of the invention.

### BRIEF DESCRIPTION OF THE DRAWINGS

The invention together with objects and advantages thereof, may best be understood by reference to the following description of the presently preferred embodiments together with the accompanying drawings in which:

FIG. 1 is a schematic plan view of a heat sink device according to an embodiment of the present invention;

FIG. 2 is a schematic view of the heat sink device as seen in the direction of the arrow A in FIG. 1;

FIG. 3 is a schematic sectional view taken along the line B-B in FIG. 2;

FIG. 4 is a schematic sectional view of a heat sink device according to another embodiment of the present invention;

FIG. 5 is a schematic sectional view of a heat sink device according to still another embodiment of the present invention; and

FIG. 6 is a schematic front view of a heat sink device according to yet still another embodiment of the present invention.

### DETAILED DESCRIPTION OF THE EMBODIMENTS

The following will describe an embodiment according to the present invention with reference to the accompanying drawings. In the drawings, the horizontal plane is defined by X-Y coordinates and the vertical direction is defined by Z coordinate.

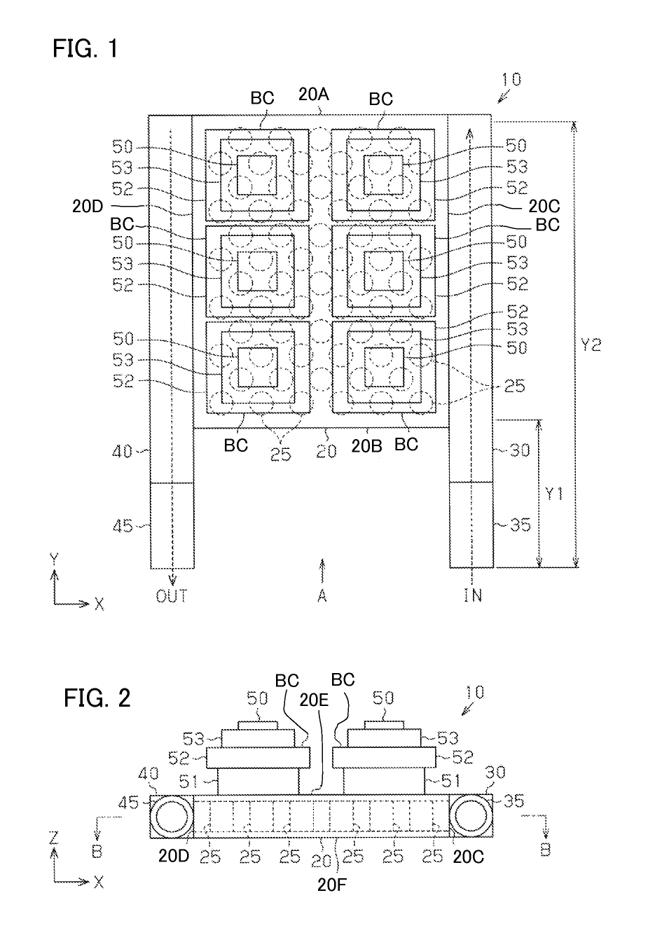

Referring to FIGS. 1 and 2, the heat sink device that is designated by reference numeral 10 includes a cooling unit 20 made of aluminum, a refrigerant inlet header 30 made of metal, and a refrigerant outlet header 40 made of metal. Cooling fluid as refrigerant is supplied into an inlet tube 35 and discharged through the refrigerant inlet header 30, the cooling unit 20, and the refrigerant outlet header 40 from an outlet tube 45.

The cooling unit 20 is of a box shape having flat top and bottom surfaces 20E and 20F. The cooling unit 20 has a rectangular shape in plan view with its short side and long side extending in X and Y directions, respectively. That is, the cooling unit 20 has short lateral surfaces 20A, 20B and long lateral surfaces 20C, 20D in plan view.

Six semiconductor elements 50 are mounted on the top surface 20E of the cooling unit 20 in two rows along the Y direction. Each semiconductor element 50 is mounted on a circuit board BC on the top surface 20E of the cooling unit 20. The circuit board BC includes a pattern layer 53 made of metal that is formed on a ceramic board 52 as an insulation board and an aluminum layer 51 formed as buffer layer below the ceramic board 52. The semiconductor element 50 is soldered to the pattern layer 53 of the circuit board BC. The aluminum layer 51 of the circuit board BC is bonded to the top surface 20E of the cooling unit 20.

Thus, the pattern layer 53 having mounted thereon the semiconductor element 50 that generates heat, the ceramic boards 52, the aluminum layer 51 (buffer layer) that relieves the stress of the ceramic board 52, and the cooling unit 20 in which cooling fluid is flowed are formed integrally.

A power semiconductor switching element is used as the semiconductor element 50. Upper and lower arms of an inverter circuit are formed by the semiconductor elements 50. Specifically, the switching elements for the upper and lower arms of U phase correspond to the first and the second semiconductor elements 50, respectively, the switching elements for the upper and lower arms of V phase to the third and the fourth semiconductor elements 50, respectively, and the switching elements for the upper and lower arms of W phase to the fifth and the sixth semiconductor elements 50, respectively. These six semiconductor elements 50 are disposed on the top surface 20E of the cooling unit 20 in such a way that three semiconductor elements 50 are arranged in Y direction in two rows in X direction. The six semiconductor elements 50 generate heat during switching operation.

As shown in FIG. 2, the refrigerant inlet header 30 has a rectangular tubular shape and extends linearly in Y direction. One end of the refrigerant inlet header 30 that is remote from the inlet tube 35 is closed. The refrigerant outlet header 40 has a rectangular tubular shape and extends linearly in Y direction. One end of the refrigerant outlet header 40 that is remote from the outlet tube 45 is closed.

The refrigerant inlet and outlet headers 30 and 40 extend horizontally parallel to each other in Y direction. Thus, the refrigerant inlet and outlet headers 30 and 40 are disposed in the same direction with each other.

The circular inlet tube 35 is connected to the other end of the refrigerant inlet header 30 that is opposite to the closed end thereof. Cooling fluid is supplied through the inlet tube 35 into the refrigerant inlet header 30. That is, one end of the refrigerant inlet header 30 is closed and the cooling fluid is introduced through the opening of the other end thereof.

The circular outlet tube 45 is connected to the other end of the refrigerant outlet header 40. Cooling fluid is drained through the refrigerant outlet header 40 and the outlet tube 45. That is, one end of the refrigerant outlet header 40 is closed and the cooling fluid is drained from the opening of the other end thereof.

The refrigerant inlet and outlet headers 30 and 40 are provided with the cooling unit 20 interposed therebetween in X direction. The closed end of the refrigerant inlet header 30 is flush with the lateral surface 20A of the cooling unit 20. The closed end of the refrigerant outlet header 40 is flush with the lateral surface 20A of the cooling unit 20.

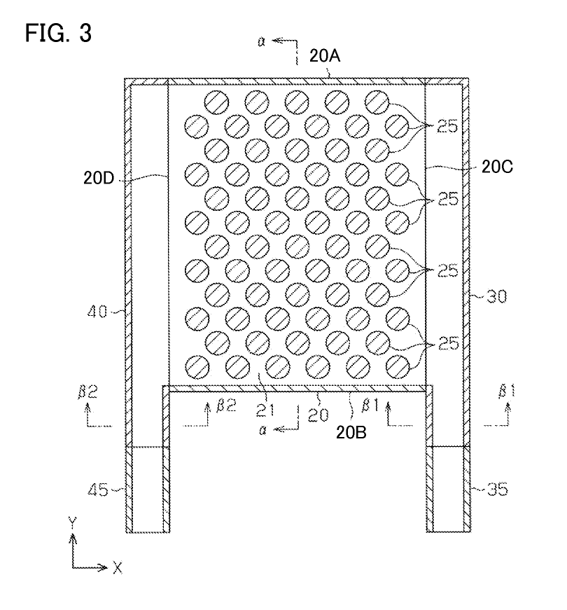

The refrigerant inlet header 30 is joined to the cooling unit 20 at the lateral surface 20C thereof. As shown in FIG. 3, the refrigerant inlet header 30 is in communication with the cooling unit 20 in the longitudinal lateral surface of the refrigerant inlet header 30. Cooling fluid is flowed into the cooling unit 20 through the part where the refrigerant inlet header 30 is in communication with the cooling unit 20.

As shown in FIG. 1, the refrigerant outlet header 40 is joined to the lateral surface 20D of the cooling unit 20. As shown in FIG. 3, the refrigerant outlet header 40 is in communication with the cooling unit 20 in the longitudinal lateral surface of the refrigerant outlet header 40. Cooling fluid is flowed out through the part where the refrigerant outlet header 40 is in communication with the cooling unit 20.

The refrigerant inlet and outlet headers 30 and 40 have the same size of dimensions. The height of the refrigerant inlet and outlet headers 30 and 40 as measured in Z direction is the same as that of the cooling unit 20. As shown in FIG. 2, the top surface 20E is flush with the upper surface of the refrigerant inlet and outlet headers 30 and 40. The bottom surface 20F of the cooling unit 20 is flush with the lower surface of the refrigerant inlet and outlet headers 30 and 40.

As shown in FIG. 3, the cooling unit 20 has therein a plurality of bar-like fins, or pin fins 25 placed side by side along the longitudinal direction of the refrigerant inlet and outlet headers 30 and 40, or Y direction and a passage 21 which is formed between any two adjacent pin fins 25 in which cooling fluid is flowed. The pin fins 25 are made of aluminum, have a cylindrical cross section. Each pin fin is arranged in a stagger manner in X and Y directions and extend in Z direction. That is, the cooling unit 20 is disposed extending from the inner ceiling surface of the cooling unit 20 downward and connected to the inner bottom surface of the cooling unit 20.

As shown in FIG. 3, the section of the cooling unit 20 taken along the line α-α serves as a passage through which cooling fluid flows in the cooling unit 20. The section of the refrigerant inlet header 30 taken along the line β1-β1 serves as a passage for the cooling fluid in the refrigerant inlet header 30. The section of the refrigerant outlet header 40 taken along the line β2-β2 serves as a passage for the cooling fluid in the refrigerant outlet header 40. It is noted that the passage area for the cooling fluid in the refrigerant inlet and outlet headers 30 and 40 is larger than that in the cooling unit 20.

The following will describe the operation of the heat sink device 10. The heat generated by the semiconductor elements 50 is transferred through the pattern layers 53 and the ceramic boards 52 of the circuit board BC to the cooling unit 20 and heat exchange occurs between the heat and the cooling fluid through the pin fins 25 in the cooling unit 20.

The cooling unit 20 in which a plurality of pin fins 25 is disposed in a stagger arrangement along the longitudinal direction of the refrigerant inlet and outlet headers 30 and 40 in the passage 21 of the cooling unit 20 for cooling fluid causes a pressure loss of a predetermined magnitude and the flow speed of the cooling fluid in the cooling unit 20 is made uniform. Therefore, the cooling performance is improved.

That is, a pressure loss of a predetermined magnitude occurs at positions where the pin fins 25 are disposed in a staggered arrangement along the longitudinal direction of the refrigerant inlet and outlet headers 30 and 40 in the passage 21 of the cooling unit 20 for cooling fluid. This causes cooling fluid to flow into the refrigerant inlet header 30. It is noted that Y1 in FIG. 1 is the distance from the inlet of the refrigerant inlet header 30 to the position of the refrigerant inlet header 30 that is the closest to the cooling unit 20 and Y2 in FIG. 1 is the distance from the inlet of the refrigerant inlet header 30 to the position of the refrigerant inlet header 30 that is farthest from the inlet of the refrigerant inlet header 30. Cooling fluid can be flowed to the closed end of the refrigerant inlet header 30 at a uniform flow speed at any position between the downstream ends of the distance Y1 and the distance Y2.

Specifically, the plural pin fins 25 are disposed in a staggered arrangement along the longitudinal direction of the refrigerant inlet and outlet headers 30 and 40, so that cooling fluid is flowed from the refrigerant inlet header 30 to the refrigerant outlet header 40 through the passage 21 which is formed between any two adjacent pin fins 25. Then, if the pressure loss at the closed end of the refrigerant inlet and outlet headers 30 and 40 is small, the cooling fluid may flow at a uniform speed by flowing in oblique direction.

Thus, the variation in the flow speed of the cooling fluid in the area cooling the semiconductor element 50 is reduced and, therefore, the flow speed is uniform irrespective of the distance from the inlet or the outlet (Y1, Y2, respectively in FIG. 1). The cooling unit according to the embodiment described above offers the following advantages.

(1) The plural pin fins 25 are disposed in a staggered arrangement along the longitudinal direction of the refrigerant inlet and outlet headers 30 and 40 in the passage 21 for cooling fluid of the cooling unit 20. Accordingly, the cooling fluid is flowed to the closed end of the refrigerant inlet header 30 before flowing into the cooling unit 20, so that the flow speed of the cooling fluid is uniform. Therefore, the variation of the heat sink performance in the cooling unit 20 can be suppressed.

(2) The cross-sectional flow area for the cooling fluid of the refrigerant inlet and outlet headers 30 and 40 is larger than that of the cooling unit 20. That is, the cross-sectional flow area of each of the refrigerant inlet and outlet headers 30 and 40 is larger than the area forming the pin fins 25 of the cooling unit 20, so that the variation of the flow speed of the cooling fluid can be reduced. Specifically, before the cooling fluid is flowed into the cooling unit 20, the cooling fluid is flowed to the closed end of the refrigerant inlet header 30, so that the flow speed of the cooling fluid is uniform. The cross-sectional area of flow passage for the cooling fluid of the refrigerant inlet and outlet headers 30 and 40 is larger than that in the cooling unit 20, so that the flow speed of the cooling fluid becomes more uniform.

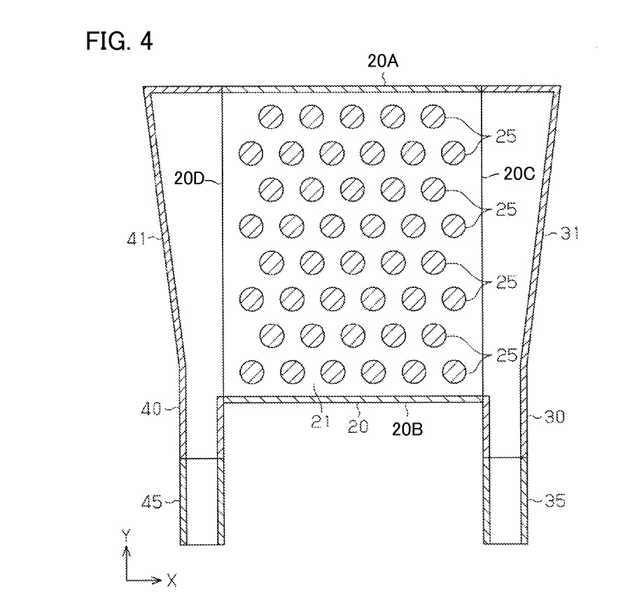

The above embodiment may be modified in various ways as exemplified below. The refrigerant inlet and outlet headers 30 and 40 do not necessarily need to be formed rectangular as shown in FIG. 1. As shown in FIG. 4, the refrigerant inlet and outlet headers 30 and 40 may be formed in a structure having divergent parts 31, 41 formed so as to make the fluid passage within the refrigerant inlet and outlet headers 30 and 40 to be wider toward the closed end. In this structure wherein the refrigerant inlet and outlet headers 30 and 40 are formed expanded toward the closed end according to the pressure loss caused by the presence of the plural pin fins 25, so that the variations of the flow speed of the cooling fluid can be reduced.

Specifically, decreasing the number of the pin fins 25 reduces the resistance against the flow of cooling fluid, so that the cooling fluid is prevented from flowing smoothly in a region of the flow passage of the refrigerant inlet header 30 that is away from the inlet thereof and also in a region of the flow passage of the refrigerant outlet header 40 that is away from the outlet thereof. In order to allow the cooling fluid to flow smoothly, the flow passage in the refrigerant inlet header 30 may have such a shape that the flow passage becomes wider toward the downstream end thereof and the flow passage in the refrigerant outlet header 40 has such a shape that the flow passage becomes wider toward the upstream end thereof. Thus, cooling fluid can be flowed easily downstream in the flow passage of the refrigerant inlet header 30, so that the flow speed of the cooling fluid becomes uniform.

According to the present invention, it may be so configured that at least one of the refrigerant inlet header 30 and the refrigerant outlet header 40 has a divergent part such as 31, 41 which allows the flow passage in the header to become wider toward the closed end thereof.

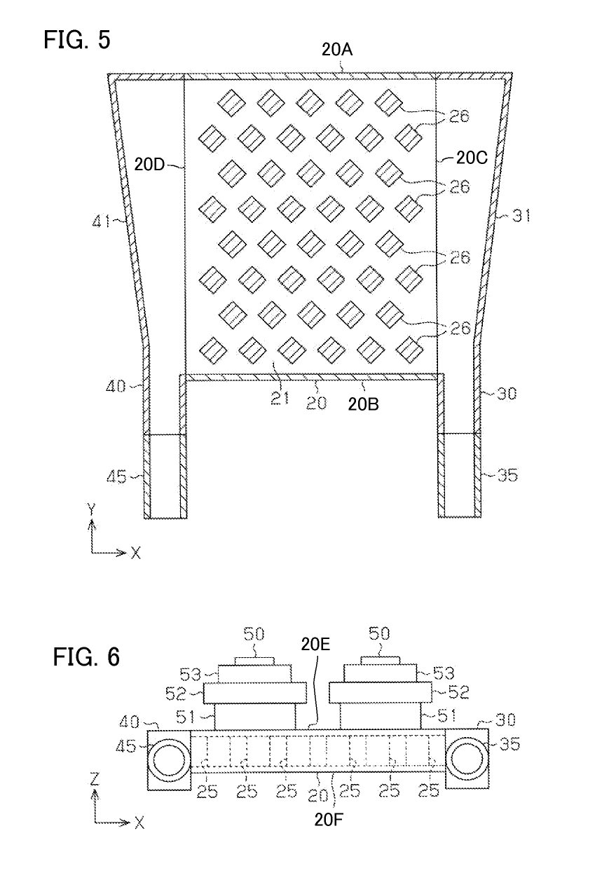

As shown in FIG. 5, the pin fins 25 may be replaced by fins 26 having a rectangular cross section or, alternatively, fins having an elliptical cross section. Additionally, the refrigerant inlet and outlet headers 30 and 40 may be formed such that their dimensions in Z direction are enlarged as shown in FIG. 6, instead of enlarging the dimensions in X direction as in the case of FIG. 4. That is, enlarging the sectional areas (flow path areas) of the refrigerant inlet and outlet headers 30 and 40 helps the cooling fluid to flow easily in the refrigerant inlet and outlet headers 30 and 40.

Specifically, the refrigerant inlet and outlet headers 30 and 40 are formed with a dimension in Z direction that is greater that that of the cooling unit 20. The flow passage area of the refrigerant inlet and outlet headers 30 and 40 can be larger than the flow passage area formed at the disposition of the pin fins 25, so that variation of the flow speed of the cooling fluid can be reduced. As shown in FIG. 6, the upper surfaces of the refrigerant inlet and outlet headers 30 and 40 are disposed with the top surfaces thereof extending flush with that of the cooling unit 20. Such disposition has effects that are advantageous in that the semiconductor elements 50 can be sealed easily by resin and that external terminals can be formed easily. Alternatively, the refrigerant inlet and outlet headers 30 and 40 may be disposed such that the lower surfaces of the refrigerant inlet and outlet headers 30 and 40 are flush with the lower surface of the cooling unit 20. In this structure, the heat sink device 10 can be mounted easily onto a case because of the flat bottom thereof.

What is claimed is:

1. A heat sink device, comprising:
a cooling unit having a refrigerant passage through which refrigerant is flowed and mounting a semiconductor element;
a refrigerant inlet header having a tubular shape, wherein one end of the refrigerant inlet header is closed and the other end of the refrigerant inlet header has an opening which allows the refrigerant to flow into the refrigerant inlet header, the refrigerant inlet header having a lateral surface in a longitudinal direction thereof and being in communication with the cooling unit through the lateral surface thereof so as to allow the refrigerant in the refrigerant inlet header to flow into the cooling unit;
a refrigerant outlet header having a tubular shape and extending in parallel with the refrigerant inlet header, wherein one end of the refrigerant outlet header is closed and the other end of the refrigerant outlet header has an opening which allows the refrigerant to flow out from the refrigerant outlet header, the refrigerant outlet header having a lateral surface in a longitudinal direction thereof and being in communication with the cooling unit through the lateral surface thereof so as to allow the refrigerant to flow out from the cooling unit; and
a plurality of pin fins placed side by side in the refrigerant passage of the cooling unit along the longitudinal direction of the refrigerant inlet header and the refrigerant outlet header.

2. The heat sink device according to claim 1, wherein at least one of the refrigerant inlet header and the refrigerant outlet header has a divergent part which becomes wider toward the closed end thereof.

3. The heat sink device according to claim 1, wherein a refrigerant flow area of each of the refrigerant inlet header and the refrigerant outlet header is larger than a refrigerant flow area of the cooling unit.
